(19) United States
(12) Patent Application Publication
(10) Pub. No.: US 2026/0269168 A1
(43) Pub. Date: Sep. 10, 2026

(54) NON-UNIFORM SUBSRATE PROCESSING USING A SCANNED SPOT ION BEAM

(71) Applicant: Applied Materials, Inc., Santa Clara, CA (US)

(72) Inventors: Jeffery A. Morse, Center Tuftonboro, NH (US); Morgan Evans, Manchester, MA (US); D. Jeffery Lischer, Acton, MA (US); Adaeze Osonkie, Beverly, MA (US); Kurt Decker-Lucke, Gloucester, MA (US); Allen Pitzer, South Hamilton, MA (US); Kyu-Ha Shim, Andover, MA (US)

(21) Appl. No.: 19/071,402

(22) Filed: Mar. 5, 2025

(51) Int. Cl. H01J 37/147; H01J 37/317

(52) U.S. Cl. CPC H01J 37/1474; H01J 37/3171; H01J 2237/043; H01J 2237/0822; H01J 2237/31711

(57) ABSTRACT

A method of processing a substrate. The method may include subjecting the substrate to a non-uniform exposure, based upon a targeted dose pattern, where the targeted dose pattern is a non-uniform pattern. The non-uniform exposure may include scanning an ion beam with respect to the substrate, along a first direction, while the substrate is scanned along a second direction, different from the first direction, during a first interval. The non-uniform exposure may further include, during a second interval, beam blanking the ion beam while the substrate is scanned along the second direction, wherein an unexposed portion of the substrate remains after the non-uniform exposure and wherein a substrate scan speed differs between the first interval and the second interval.

### FIELD

The present embodiments relate to ion beam processing of substrates, and more particularly to non-uniform ion beam processing to selectively manage substrate properties.

### BACKGROUND

Devices such as integrated circuits, memory devices, and logic devices may be fabricated on a substrate such as a semiconductor wafer by a combination of deposition processes, etching, ion implantation, annealing, and other processes. Often, complete fabrication of devices and related circuitry may entail many hundreds of operations, including dozens of lithography operations.

Among others, ion beam processing may be performed to selectively treat a substrate or wafer, by exposing the substrate to varying ion dose and/or varying ion energy of a given ion species or set of ion species. Depending upon the application, such as selective doping, or selective stress management, the substrate may be treated to an ion exposure having a complex ion dose pattern (or, simply a “dose pattern”), for example. As such, a targeted dose pattern for exposing a substrate may be implemented by various combinations of scanning a substrate, scanning an ion beam, and so forth.

One issue with known approaches to selective substrate treatment using an ion beam is that the process for implementing a dose pattern may be inefficient, either in terms of the ion dose required, or in terms of the duration of processing to complete the dose pattern.

With respect to these and other considerations the present embodiments are provided.

### BRIEF SUMMARY

In one embodiment, a method of processing a substrate is provided. The method may include subjecting the substrate to a non-uniform exposure, based upon a targeted dose pattern, where the targeted dose pattern is a non-uniform pattern. The non-uniform exposure may include scanning an ion beam with respect to the substrate, along a first direction, while the substrate is scanned along a second direction, different from the first direction, during a first interval. The non-uniform exposure may further include, during a second interval, beam blanking the ion beam while the substrate is scanned along the second direction, wherein an unexposed portion of the substrate remains after the non-uniform exposure, and wherein a substrate scan speed differs between the first interval and the second interval.

In another embodiment, an additional method of processing a substrate is provided. The method may include subjecting the substrate to a non-uniform exposure, based upon a targeted dose pattern, where the targeted dose pattern is a non-uniform pattern. The non-uniform exposure may include scanning a spot ion beam with respect to the substrate, along a first direction, while the substrate is scanned along a second direction, different from the first direction. As such, the spot ion beam may be scanned in a non-uniform manner, and a scan speed of the substrate may be varied while the substrate is scanned, according to a geometry of the targeted dose pattern.

In a further embodiment, another method of processing a substrate is provided. The method may include receiving a targeted dose pattern for processing the substrate with a spot ion beam, receiving of spot beam measurement of the spot ion beam, receiving a scan recipe for the spot ion beam, and generating a predicted dose pattern based upon the spot beam measurement and the scan recipe. The method may further include exposing the substrate to the spot ion beam in a non-uniform exposure, according to the scan recipe in order to implement the targeted dose pattern, when an error between the targeted dose pattern and the predicted dose pattern is below a threshold.

### BRIEF DESCRIPTION OF THE DRAWING

FIG. 1A shows an exemplary system in accordance with the present disclosure;

FIG. 1B shows further details of a controller according to some embodiments of the disclosure;

FIG. 2 is a composite image depicting the geometry and time dependence of the position of a spot ion beam and substrate, according to one embodiment of non-uniform processing;

FIG. 3 is a composite image depicting the geometry and time dependence of the position of a spot ion beam and substrate, according to another embodiment of non-uniform processing;

FIG. 4 is a graph that depicts the substrate throughput and substrate out-of-plane distortion (OPD) response, when subject to non-uniform processing according to different embodiments;

FIG. 5A depicts a spot beam shape in a reference plane;

FIG. 5B depicts a targeted dose map on a substrate, to be implemented using the spot beam of FIG. 5A;

FIG. 5C is a predicted dose map on the substrate based upon a convolution of the spot beam image of FIG. 5A and the targeted dose map of FIG. 5B;

FIG. 5D presents an enlarged region of the predicted dose map of FIG. 5C;

FIG. 6 is a composite image depicting the geometry and time dependence of the position of a spot ion beam and substrate, according to a reference scenario for non-uniform processing;

FIG. 7A is a composite image depicting the geometry and time dependence of the position of a spot ion beam and substrate, according to yet another embodiment of non-uniform processing;

FIG. 7B is illustrates two different substrate scan curves according to embodiments of the disclosure;

FIG. 8 is a composite image depicting the geometry and time dependence of the position of a spot ion beam and substrate, according to still another embodiment of non-uniform processing;

FIG. 9A is a graph that depicts the substrate throughput and substrate OPD response, when subject to non-uniform processing according to additional embodiments;

FIG. 9B is a graph that depicts the substrate throughput and substrate OPD response, when subject to non-uniform processing according to further embodiments;

FIG. 9C depicts another spot beam shape in a reference plane;

FIG. 9D depicts a targeted dose map on a substrate, to be implemented using the spot beam of FIG. 9C;

FIG. 9E depicts another predicted dose map on the substrate based upon a convolution of the spot beam image of FIG. 9C and the targeted dose map of FIG. 9D;

FIG. 10A depicts a first targeted dose pattern;

FIG. 10B depicts a second targeted dose pattern;

FIG. 10C depicts a composite targeted dose pattern, composed of an addition of the targeted dose pattern of FIG. 10A and the targeted dose pattern of FIG. 10B;

FIG. 10D depicts a third targeted dose pattern;

FIG. 10E depicts a fourth targeted dose pattern;

FIG. 10F depicts a composite targeted dose pattern, composed of an addition of the targeted dose pattern of FIG. 10D and the targeted dose pattern of FIG. 10E;

FIG. 10G is a composite illustration that depicts the application of multiple implants under different implant conditions to generate a composite targeted dose pattern;

FIG. 11A is an exploded view of a proximity mask and substrate;

FIG. 11B is a composite image depicting the geometry and time dependence of the position of a spot ion beam and substrate of FIG. 12A with proximity mask in place, according to yet another embodiment of non-uniform processing;

FIG. 12 depicts a complex targeted dose pattern;

FIG. 13 depicts an exemplary process flow;

FIG. 14 depicts another exemplary process flow;

FIG. 15 depicts a further exemplary process flow; and

FIG. 16 depicts an additional exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The embodiments described herein relate to techniques and apparatus for improved selective processing of a substrate using a scanned ion beam. The present embodiments present an approach to selective substrate processing that employs novel combinations of substrate scanning, ion beam scanning, and beam blanking. In various non-limiting embodiments, the present approach may be applied for processing a patterned stress compensation layer on the substrate surface; generating a patterned ion implant dose into a substrate, performing selective area etching across a substrate, and so forth.

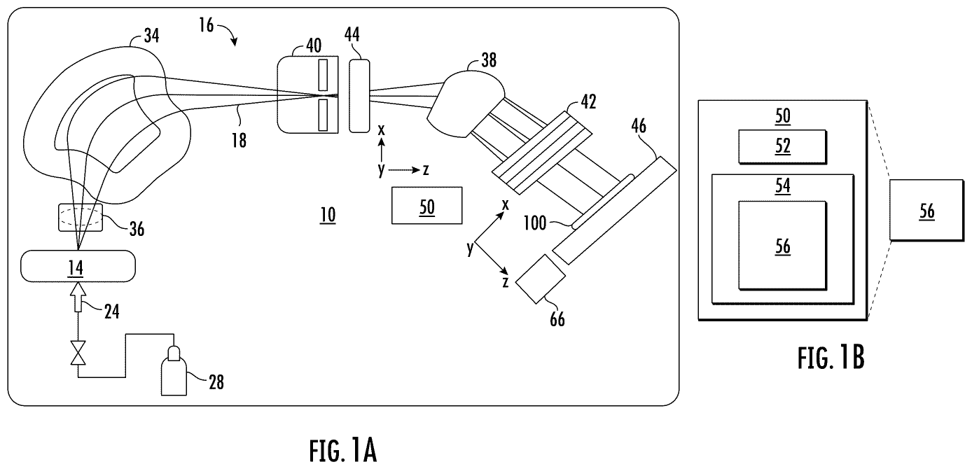

Referring now to FIG. 1A, an exemplary system in accordance with the present disclosure is shown. The ion implantation system (hereinafter “system”) 10 represents a process chamber containing, among other components, an ion source 14 for producing an ion beam 18 and a series of beam-line components 16. The ion source 14 may comprise a chamber for receiving a flow of gas 24 and generating ions therein. The ion source 14 may also comprise a power source and an extraction electrode assembly disposed near the chamber. The beam-line components 16 may include, for example, a mass analyzer 34, a first acceleration or deceleration stage 36, a collimator 38, a mass resolving slit 40, a scanner 44 to scan the ion beam 18, and other suitable downstream beamline components such as an energy filter 42, to accelerate the ion beam 18, decelerate the ion beam 18, shape the ion beam 18, scan the ion beam 18, and so forth.

In particular embodiments, the beam-line components 16 may filter, focus, accelerate, decelerate, and otherwise manipulate ions or the ion beam 18 to have a desired species, shape, energy, and other qualities. The ion beam 18 passing through the beam-line components 16 may be directed toward a substrate 100 mounted on a substrate stage 46 or clamped within a process chamber. As appreciated, the substrate may be moved using a control mechanism 66 in one or more dimensions (e.g., translate, rotate, and tilt). As shown, there may be one or more feed sources 28 operable with the chamber of the ion source 14. In one embodiment, the substrate stage 46 includes a heating stage capable to heat the substrate 100 to elevated temperature.

In some embodiments, the ion implantation system 10 may include a scanner (not shown), to scan the ion beam 18. For example, the ion beam 18 may be provided as a pencil beam or spot beam that is scanned with the X-Y plane of the Cartesian coordinate system. For example, a scan generator (not separately shown) may deliver a scan signal, such as an oscillating voltage, to a pair of electrode plates that generate an oscillating electric field at a scan frequency in the kHz range, such as 1 kHz, 2 kHz, 5 kHz, according to some non-limiting embodiments.

In various embodiments, different species may be used as the ions to implant into the substrate and/or films deposited thereupon to alter their material properties. Non-limiting examples of suitable ions include silicon (Si), boron (B), carbon (C), oxygen (O), germanium (Ge), phosphorus (P), arsenic (As),, carbon (C), and neon (N) ions, and so forth as to control substrate properties.

Although non-limiting, the ion source 14 may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art.

FIG. 1B shows further details of the controller 50. In this embodiment, the controller 50 may include a processor 52, such as a known type of microprocessor, dedicated processor chip, general purpose processor chip, or similar device. The controller 50 may further include a memory or memory unit 54, coupled to the processor 52, where the memory unit 54 contains a selective area processing routine 56 to implement the techniques and methods as disclosed herein, to control an ion implanter for scanning a spot ion beam and a substrate.

The memory unit 54 may comprise an article of manufacture. In one embodiment, the memory unit 54 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

The ion source 14 may generate the ion beam 18 for processing a substrate 100. In various embodiments, the ion beam (in cross-section) may have a targeted shape, such as a spot beam, as known in the art. In the Cartesian coordinate system shown, the direction of propagation of the ion beam 18 may be represented as parallel to the Z-axis, while the actual trajectories of ions with the ion beam 18 may vary. In order to process the substrate, the ion beam 18 may be accelerated to acquire a target energy by establishing a voltage (potential) difference between the ion source 14 and the wafer (substrate).

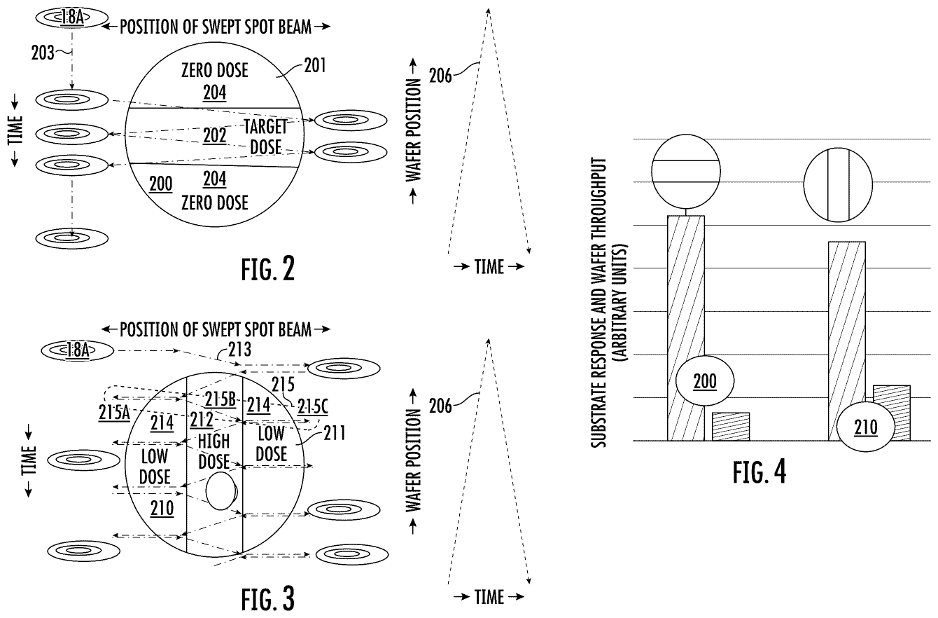

FIG. 2 is a composite image depicting the geometry and time dependence of the position of a spot ion beam and substrate, according to one embodiment of non-uniform processing. In the left portion of FIG. 2 a cross-section of a spot ion beam 18A is shown together with a top plan view of a substrate 201, to be processed by the spot ion beam 18A. The shape of the spot ion beam 18A in cross-section may be circular, elliptical, or irregular, and may be non-uniform in density across the cross-section. Note that in the scenario of FIG. 2, the spot ion beam, meaning the spot ion beam 18A, is to be scanned across the surface of substrate 201. The spot ion beam 18A may be scanned back and forth across the substrate 201, along a first direction, meaning, in a horizontal manner with respect to substrate 201 in the image of FIG. 2. In some non-limiting embodiments, the spot ion beam 18A may be scanned at a frequency of 500 Hz, 1000 Hz, 2000 Hz, 5000 Hz, and so forth.

In order to impart a targeted dose pattern 200 into the substrate 201, the substrate 201 may be scanned along a second direction, such as perpendicularly to the first direction, meaning in a vertical direction in the FIG. 2. For the purposes of clarity of explanation, in FIG. 2, the position of the spot ion beam 18A with respect to the substrate 201 is shown at different instances. As shown, the spot ion beam 18A may be scanned from a left position where the spot ion beam 18A is located to the left of the substrate 201, in a path that crosses the substrate 201 to a right position where the spot ion beam 18A is located to the right of the substrate 201. Note that the spot ion beam 18A may be scanned back and forth along a given scan line in a first direction, while the substrate 201 moves in a direction perpendicular to the scan line. In various non-limiting embodiments, the substrate may be scanned back and forth along the second direction, such as vertically in the image of FIG. 2. A frequency of scanning for the substrate 201 may be on the order of 0.1 Hz to 1 Hz in some non-limiting embodiments. Note also in the composite image of FIG. 2, the vertical direction also represents a time axis. Thus, at different instances in time, as the substrate 201 is scanned along a second direction (vertical direction) with respect to the spot ion beam 18A, the spot ion beam 18A will be located at different vertical positions. The curve 203 (in dashes) in FIG. 2 thus represents a scan curve that expresses the change in position of the spot ion beam 18A with respect to the substrate 201 as a function of time, with the arrow representing the direction of movement for the spot ion beam 18A. Note that, while the curve 203 describes a handful of cycles that correspond to sweeps of the spot ion beam 18A back and forth ‘horizontally’ across the substrate 201, in practical implementations, the spot ion beam 18A may be scanned for many dozens of cycles over the duration of one cycle of scanning the substrate 201 ‘vertically’ up and down. Thus, the curve 203 may represent 50 cycles of scanning of the spot ion beam 18A, 100 cycles, 200 cycles, 500 cycles, and so forth. Note that the curve 203 corresponds to one half of the substrate scan curve 206, in that the spot ion beam 18A traces the path of curve 203 once while the substrate 201 is scanned vertically corresponding to substrate scan curve 206 from bottom to top in the figure; the spot beam 18A then traces the path of curve 203 in a reverse direction while the substrate 201 is scanned vertically from top to bottom along substrate scan curve 206.

In the scenario of FIG. 2, the targeted dose pattern 200 includes an unexposed portion that is composed of two regions, designated as zero dose regions 204 that are separated by a middle region 202. In some embodiments, the middle region 202 may be arranged as a horizontal stripe, where the target ion dose is uniform across the substrate 201 within the middle region 202. In order to implement the targeted dose pattern 200, the spot ion beam 18A may initially be held at a location off the substrate 201, such as to the left, as shown in FIG. 2, while the substrate 201 is scanned upwardly with respect to the spot ion beam 18A. The spot ion beam 18A may be maintained off the substrate 201 so as to not impact the substrate 201 until sufficient time has elapsed for the substrate to reach the vertical position of the top of the middle region 202, with respect to the spot ion beam 18A. Thus, the curve 203 shows an initial vertical portion that lies to the left of substrate 201, meaning that for a given time interval, as represented by the length of segment of curve 203, the beam is “blanked,” meaning the spot ion beam 18A is held off the substrate 201, and may be stationary and is not scanned horizontally. Said differently, the terms “blanked” or “beam blanking,” as used herein, refer to setting and/or maintaining an ion beam at a position so as not to impinge on the substrate, while the substrate is being scanned. More particularly, during beam blanking, the ion beam is maintained off the substrate for a sufficient interval while the substrate is scanned along a substrate scan direction, so that an unexposed region of the substrate is created that is not impacted by the ion beam.

Subsequently, when the spot ion beam 18A is located adjacent to the middle region 202, to be implanted, scanning of the spot ion beam 18A commences, as shown by the sloped portions of the curve 203. The faster the spot ion beam 18A is scanned, the more horizontal the slope of the curve 203 will be, for a given scan speed of the substrate 201.

In the implementation of FIG. 2, the assumption is that the spot ion beam 18A is scanned back and forth at a uniform speed to generate the middle region 202, while the substrate 201 is also scanned up and down at a uniform speed, as depicted by the substrate scan curve 206, where time is represented on the horizontal direction and substrate position is represented on the vertical direction. Note that the substrate scan curve 206 represents one scan cycle where the substrate 201 is scanned back and forth, while in various embodiments, the substrate 201 may be scanned multiple times. The amplitude of the substrate scan curve 206 may be such that the substrate is moved at least a distance corresponding to the vertical height or diameter of the substrate 201, in some embodiments.

As such, a uniform ion dose may be imparted into the middle region 202, while the zero dose regions 204 are completely unexposed to the spot ion beam 18A. Thus, the dose pattern imparted into substrate 201 may be suitable for correcting an initial pattern of substrate out-of-plane distortion (OPD), such as where an infinite dose ratio is called for, in regards to different regions of an implantation pattern that are to be imparted into a stress compensation layer, for example. Note that the substrate throughput for the scenario of FIG. 2 will generally be the same as the throughput for a substrate that is implanted over the entirety of the surface with the dose of the middle region 202. Thus, while the total dose may be lower in the scenario of FIG. 2 than if the entire substrate is implanted, processing rate does not improve.

FIG. 3 is a composite image depicting the geometry and time dependence of the position of a spot ion beam and substrate, according to another embodiment of non-uniform processing. In this embodiment, the depiction of the movement of the substrate 211 and spot ion beam 18A may be generally the same as in FIG. 2. In this case, a targeted dose pattern 210 has a similar shape to the targeted dose pattern 200 of FIG. 2, with a middle region 212 that may be considered a greater dose region, being rotated with respect to the middle region 202. A difference in the targeted dose pattern 210 is that two outer regions that straddle the middle region 212 are lesser exposed regions that are termed as low dose regions 214 that are implanted with a finite ion dose rather than zero dose.

In the scenario of FIG. 3, the substrate 211 is scanned at a uniform speed as in FIG. 2, while the spot ion beam 18A is swept across the substrate 211 during an entirety or nearly an entirety of the time the substrate 211 is scanned. In this case, the spot ion beam 18A is scanned in a non-uniform manner where the scan speed may be a first speed when the spot ion beam 18A is over the low dose regions 214, and the scan speed is a second speed, less than the first speed, when the spot ion beam 18A is over the middle region 212 (labeled high dose in t he figure). This non-uniform scanning is represented by the curve 213, similar to the curve 203 of FIG. 2. In particular, FIG. 3 highlights a spot beam scan 215 segment that represents a single scan portion of the curve 213, meaning a single pass of the spot ion beam 18A from left to right across the substrate, shown. In the spot beam scan segment 215, the speed of the spot ion beam 18A is initially higher over the low dose region 214 to the left. This greater speed is evidenced by the near-horizontal slope of the spot ion beam 18A position vs time in the scan portion 215A over low dose region 214 to the left, meaning that the spot ion beam traverses across the low dose region 214 over a very short time interval, as shown along the vertical axis to the left, representing time. Over the middle region 212, the scan portion 215B is more sloped, indicating that a larger time span (vertical distance) is required to traverse middle region 212, while over the low dose region 214 to the right, the scan portion 215C is again nearly horizontal.

Thus, the spot ion beam 18A spends relatively less time over the low dose regions 214 and imparts a relatively lower total ion dose therein as compared to in the middle region 212. Note that practical dose ratios of up to 100:1 or greater between the ion dose of middle region 212 and low dose regions 214 are achievable using present day capabilities of ion implanters. Thus, a similar effect on some substrate properties, such as change of OPD, may be achieved in the scenario of FIG. 3 as compared to the scenario of FIG. 2. Note also that the substrate processing throughput in FIG. 3 scales with the dose ratio and is inversely proportional to the width of the middle region 212.

FIG. 4 is a graph that depicts the substrate throughput and substrate OPD response, when subject to non-uniform processing according to different embodiments. In particular, two sets of data are compared, where the left-hand set of data illustrates the results for processing a silicon substrate with a 200 keV N ⁺ion beam where the geometry of the targeted implant pattern corresponds to the geometry of FIG. 2. In this example, 2e15/cm² total ion dose is implanted into the middle region (aligned horizontally as shown in the insert) at 3 mA beam current while the substrate is scanned vertically. The change in the OPD engendered by this targeted implant pattern is shown in relative terms, with some examples being in the range up to hundreds of micrometers. The substrate throughput is also shown in relative terms, with some examples ranging up to tens of wafers per hour. The right-hand set of data illustrates the results for processing a silicon substrate with a 200 keV N⁺ ion beam where the geometry of the targeted implant pattern corresponds to the geometry of FIG. 3. In this example, 2e15/cm² total ion dose is likewise implanted into the middle region (this time, aligned vertically, as shown in the insert) at 1.9 mA beam current while the substrate is scanned. The change in the OPD engendered by this targeted implant pattern is approximately 90% of the OPD change in the left hand graph, while the throughput is more than doubled. Thus, the arrangement of FIG. 3 increases the substrate throughput by more than 100% while generating approximately 90% of the reduction in OPD, as compared to the arrangement of FIG. 2.

Note that in various embodiments, before processing a substrate to implement a targeted implant pattern by non-uniform processing, a predicted implant pattern may be determined and compared to the targeted implant pattern. In particular, the predicted implant pattern (also referred to as a predicted dose map) may be generated by convoluting various predetermined or known features, such as a dose map grid, a beam shape of the spot ion beam, or other beam, process, or tool characteristics with a targeted scan rate of the ion beam shape across the substrate and a targeted scan rate of the substrate.

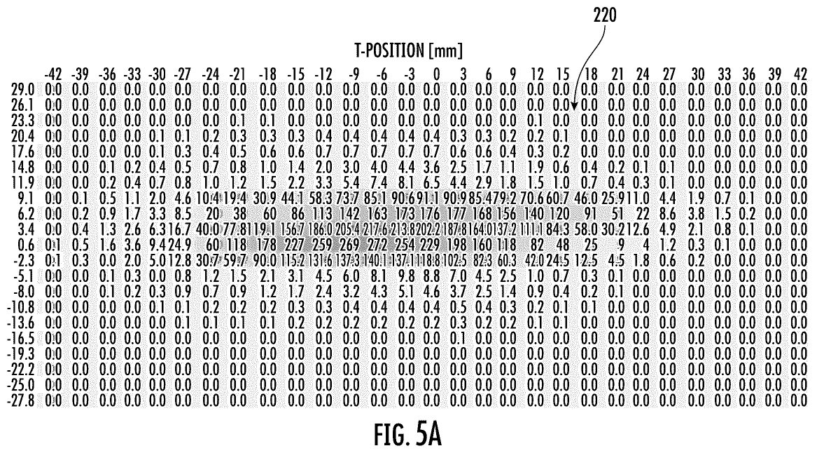

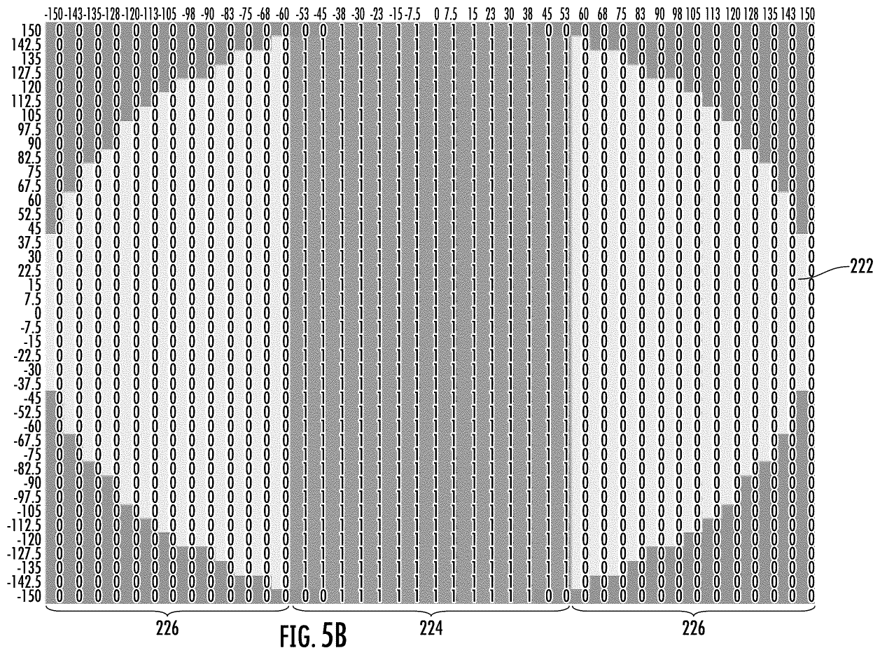

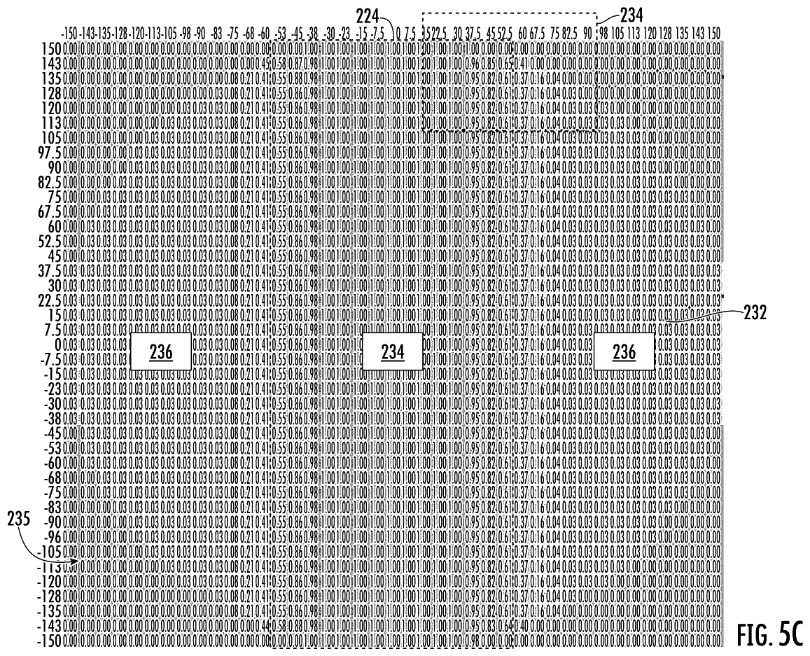

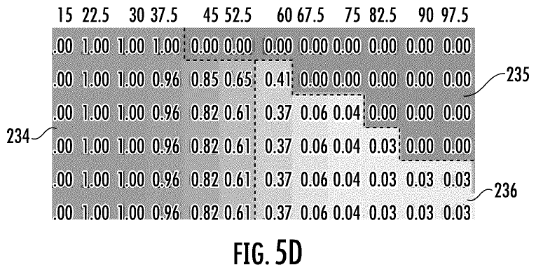

FIG. 5A depicts a spot beam shape 220 in a reference plane. The spot beam shape 220 may represent the intensity of a spot beam in plane near the plane of a substrate to be processed. Note that the spot beam shape 220 may be somewhat irregular and somewhat non-uniform in intensity. Thus, the spot beam shape 220 may be determined by a current monitor that monitors total beam current or dose as a function of position.

FIG. 5B depicts a targeted dose map 222 on a substrate, to be implemented using the spot beam of FIG. 5A. In this example, the targeted dose map corresponds to a pattern of ion dose over a set of grid point in a 2-dimensional grid, where a middle region 224 is to receive a relative dose of 1 and the outer regions 226 are to receive a relative dose of zero. Each grid point in the targeted dose map 222 represents a given ion dose to be delivered to that grid point.

FIG. 5C is a predicted dose map 232 on the substrate based upon a convolution of the spot beam image of FIG. 5A and the targeted dose map of FIG. 5B, as well as a variable spot beam scan rate, consistent with the embodiment of FIG. 3. Again, each grid point in the predicted dose map 232 represents a given ion dose to be delivered to that grid point. To illustrate this fact, FIG. 5D presents an enlarged region 238 of the predicted dose map, showing portions of a middle region 234, outer regions 236, as well as off-wafer region 235. As shown, the dose values may be normalized so that the highest value in the middle region 234 is 1.00.

As illustrated the middle region 234 is somewhat blurred on the edges, meaning there is no step function change between middle region 234 and outer regions 236, as in the targeted dose map 222. Moreover, the outer regions 236 exhibit a finite, if small, ion dose, where most of the relative dose values are in a range of 0.01 to 0.08 as compared to the relative dose of 1 in the middle region 234. Thus, the relative dose values at different grid points in the middle region 234 and the outer regions 236 of predicted dose map 232 may differ from their counterparts in the targeted dose map 222. Note that in the embodiment of FIG. 5B, the targeted dose map 222 may call for the outer regions 236 to exhibit a dose of zero. In contrast, the actual dose values in the outer regions 236 of predicted dose map 232 are in a range of ~0.01 up to over 0.30 for grid points corresponding to the grid points of outer regions 226 of targeted dose map 222 that are adjacent to the middle region 224. In different embodiments, if the error or difference between the values in the targeted dose map 222 and predicted dose map 232 are below a threshold, then processing of a substrate using the ion beam 220 will commence. A threshold may be based upon an evaluation of pattern similarity between the targeted dose map 222 and predicted dose map 232 by evaluating differences at each grid point (pixel) over an entirety of each of the maps. The evaluation of differences may involve methods such as Mean Square Error, wherein the error at each pixel is squared, the square error is summed, and a square root taken for the summed square error.

Note that in some embodiments, in addition to the aforementioned factors, a predicted dose map may further represent a convolution of a scan rate of a substrate, including a variable substrate scan rate.

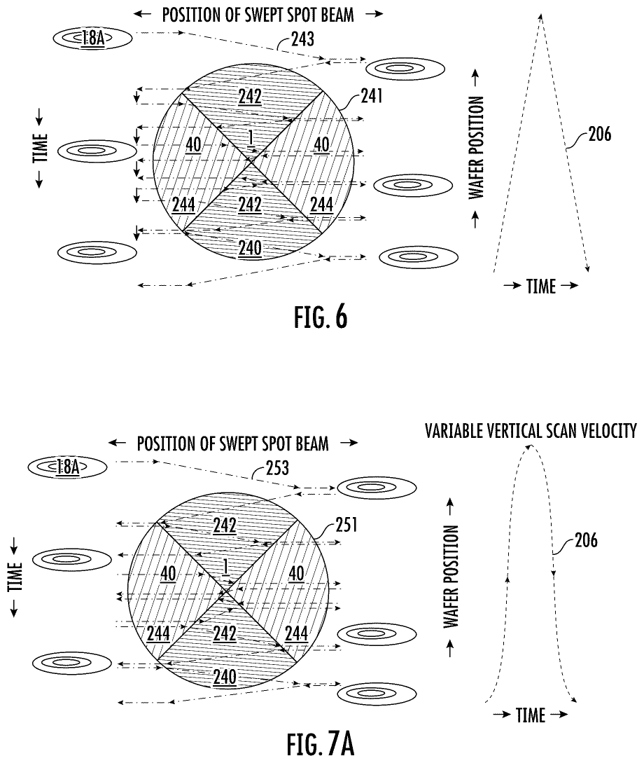

FIG. 6 is a composite image depicting the geometry and time dependence of the position of a spot ion beam and substrate, according to a reference scenario of non-uniform processing. In this example, a substrate 241 is scanned back and forth at a uniform rate, as indicated by the substrate scan curve 206. In this example, the targeted dose pattern 240 is composed of a set of wedge shapes defined by high dose regions 242 and low dose regions 244. The high dose regions 242 are characterized by a relatively greater width at the top and bottom of the substrate 241, where the width narrows to a point at the center of the substrate 241. The high dose regions are formed by scanning the spot ion beam 18A in a non-uniform manner along a scan path 243, and in particular by scanning the spot ion beam 18A at a relatively faster scan speed (such as a relative scan speed value of 40),, when the spot ion beam 18A is over the low dose regions 244, as compared to the scan speed when the spot ion beam 18A is over the high dose regions 242 (such as a relative scan speed value of 1). Note that the scan path for the spot ion beam 18A in this embodiment and in other embodiments, is depicted as a path in a two dimensional time-position framework, while in a Cartesian two-dimensional space, the spot ion beam 18A is scanned back and forth along a line. To define the wedge shapes, the commencing of the relatively slower scan speed is arranged to coincide with the edge of the high dose regions 242. Note that the scan speed of the spot ion beam 18A may also be decreased as the substrate 241 is scanned under the spot ion beam 18A towards the center of the substrate 241. Note that the scan path 243 may also entail intervals where the spot ion beam 18A is maintained off the substrate 241, for a ‘wait time,’ as indicated by the vertical arrows of scan path 243 to the left of substrate 241.

Note that in FIG. 6, the wait time during which interval, the substrate 241 is scanned, is less than the time required to scan the substrate 241 through a distance equivalent to the heigh of the spot ion beam 18A along the substrate scan direction (vertical direction). Thus, when scanning of the spot ion beam 18A resumes across the substrate 241, there will be no region of the substrate 241 that is unexposed to the spot ion beam. However, for regions of the substrate 241 adjacent to the spot ion beam 18A during the wait time, these regions will receive effectively less ion dose, so that the adjusting of wait time of the spot ion beam 18A may be used to adjust the ion dose received by substrate at a given location. In particular, especially for the narrower portions of the high dose regions 242, in order that the total ion dose be correctly applied by the spot ion beam 18A, the wait times may need to be increased so that the ion dose does not exceed the targeted amount for a given scan line across the substrate 241. However, the use of these wait times during to processing of substrate 241 may unduly restrict the throughput or process time for substrates to be processed.

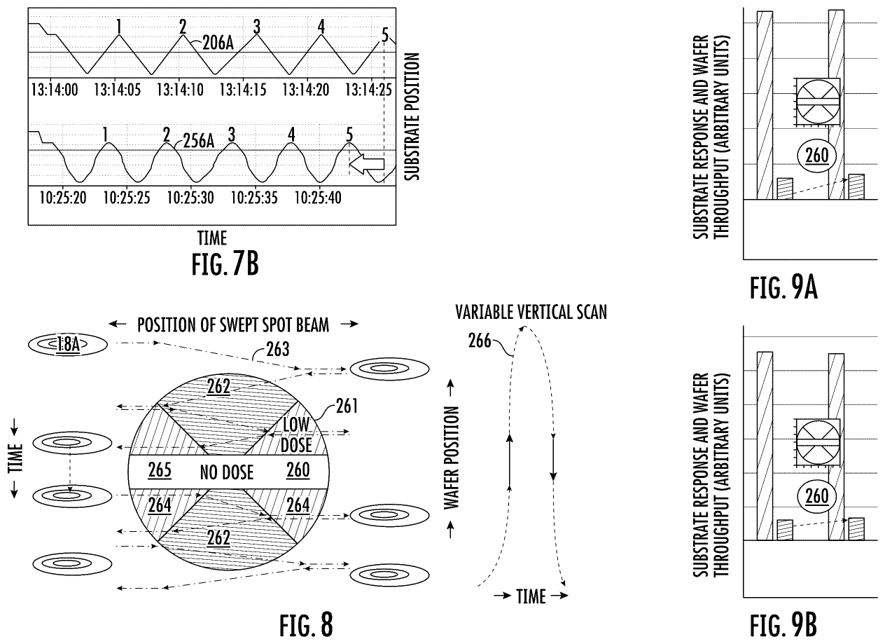

FIG. 7A is a composite image depicting the geometry and time dependence of the position of a spot ion beam and substrate, according to yet another embodiment of non-uniform processing. In this example, a substrate 251 is scanned back and forth at a non-uniform rate, as indicated by the substrate scan curve 256. In this example, the targeted dose pattern 240 may be as described with respect to FIG. 6. The spot ion beam 18A is scanned along a scan path 253 that is similar to the scan path 243. A difference is that the substrate scan curve 256 represents a variable scan speed for the substrate during a given substrate scan. In particular, the scan speed for the substrate 251 increases toward the middle of the substrate 251 where the width of the high dose regions 242 is narrower. This increasing of substrate 251 scan speed has the effect of decreasing the wait time of the spot ion beam 18A off the substrate, and therefore leads to an increased substrate throughput.

FIG. 7B is illustrates two different experimental substrate scan curves according to embodiments of the disclosure. A substrate scan curve 206A may represent the extension of the substrate scan curve 206 to multiple cycles, where one scan cycle involves scanning the substrate back and forth, in opposite directions. In the example of FIG. 7B, approximately 41/2 cycles for substrate scan curve 206A are visible in the interval between instances shown as a T1 and a time T2. A substrate scan curve 256A may likewise represent an extension of the substrate scan curve 256 to multiple cycles. In the example of FIG. 7B, approximately 5 cycles for substrate scan curve 256A are visible in the interval between instances shown as a T1 and a time T2. Assuming, for example, that five cycles are sufficient to complete implementation of the targeted dose pattern 240, the embodiment that employs the variable substrate scan approach, using substrate scan curve 256, requires less time, thus facilitating higher substrate throughput.

FIG. 8 is a composite image depicting the geometry and time dependence of the position of a spot ion beam and substrate, according to still another embodiment of non-uniform processing. In this example, a targeted dose pattern 260 is generated that is similar to target dose pattern 240, with high dose regions 262 (in one example, formed with a relative scan speed value of 1) having a general wedge shape, and low dose regions 264 (in one example, formed with a relative scan speed value of 40). A difference is that that targeted dose pattern 260 includes an unexposed portion, denoted in the figure as middle region 265 that is zero dose, and arranged as a horizontal stripe. The targeted dose pattern 260 is achieved when a substrate 261 is scanned back and forth at a non-uniform rate, as indicated by the substrate scan curve 266. The spot ion beam 18A is scanned in a non-uniform manner along a scan path 263 that is similar to the scan path 253. A difference is that the spot ion beam 18A is blanked where the spot ion beam 18A is maintained off the substrate 261 for an interval while the substrate 261 is scanned vertically through the vertical distance (along the second direction) that defines the middle region 265. Thus, the scan path 263 includes a vertical segment representing a time interval where the spot ion beam 18A is maintained off the substrate 261. Note that the substrate scan curve 266 may be similar to the substrate scan curve 256 where the relative scan speed increases when the relative position of the spot ion beam 18A is located more closely to the middle of the substrate 261. Moreover, when the substrate 261 is located at the vertical range where the spot ion beam 18A is to be blanked, the scan speed of the substrate 261 may be maximized. Thus, the substrate throughput to generate the targeted dose pattern 260 may be increased with respect to the scenario of FIG. 7. More generally, in scenarios where the targeted dose pattern admits, such as where an unexposed portion is created, such as by beam blanking, the substrate may be scanned with a non-uniform velocity along the substrate scan direction in the following manner. A greater exposed region, and a lesser exposed region are generated, in addition to the unexposed portion, where a first speed of the substrate at the unexposed portion is relatively greater than a second speed of the substrate at the lesser exposed region, and is relatively greater than a third speed of the substrate at the greater exposed region. In the example of FIG. 8, the substrate speed is fastest at the unexposed portion (middle region 265), and becomes slower as the spot ion beam 18A begins to sweep over the substrate to generate the low dose regions 264 (lesser exposed region). The substrate speed becomes still slower as the substrate is scanned further, where the spot ion beam 18A is swept in a manner to generate increasingly wide dimensions for the high dose regions 262 (greater exposed regions), toward the top or bottom of the substrate 261 as shown.

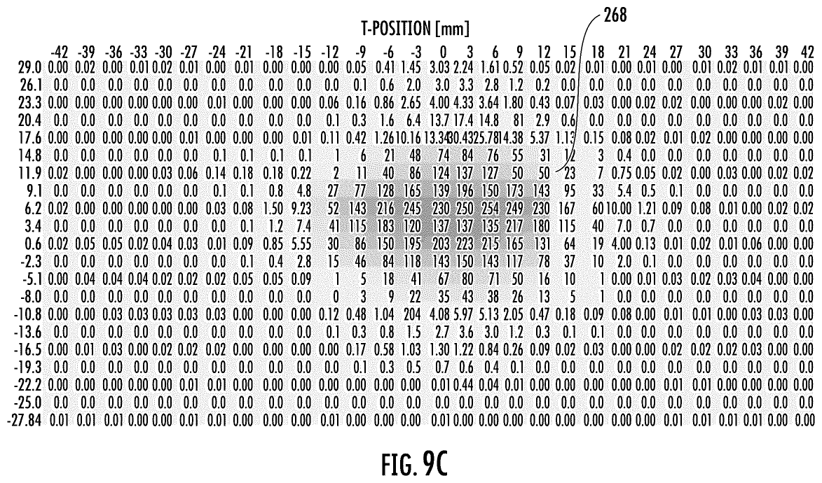

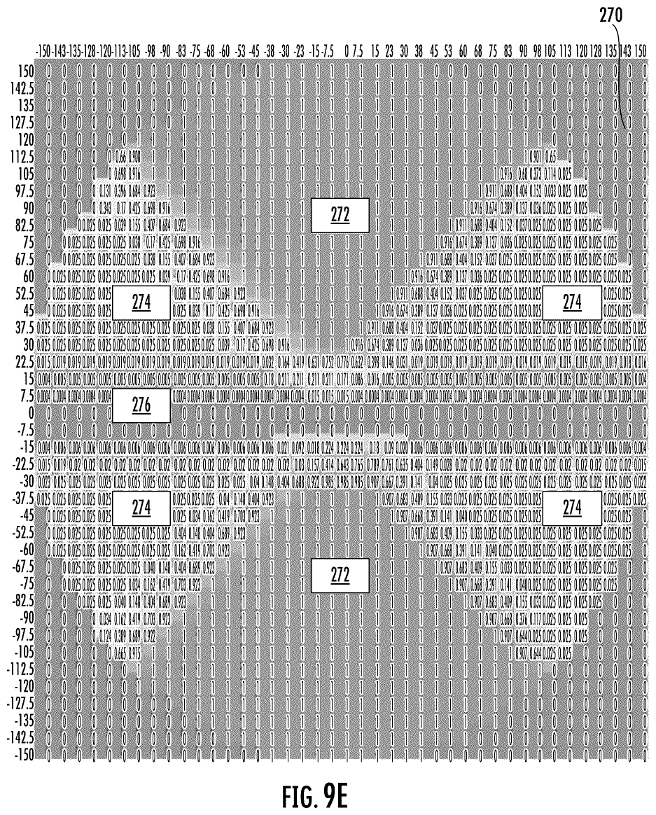

FIG. 9A is a graph that depicts the substrate throughput and substrate OPD response, when subject to non-uniform processing according to different embodiments. In particular, two sets of data are compared, where the left-hand set of data illustrates the results for processing a silicon substrate with a 200 keV N⁺ ion beam where the geometry of the targeted implant pattern corresponds to the targeted dose pattern 260. However, unlike the scenario of FIG. 8 the substrate is not scanned at variable speed. In this example, 2e15/cm² total ion dose is implanted into the high dose regions 262. The change in the OPD engendered by this targeted implant pattern and the substrate throughput are shown in relative terms. The right-hand set of data illustrates the results for processing a silicon substrate with a 200 keV N⁺ ion beam where the geometry of the targeted implant pattern corresponds to the geometry of FIG. 8 with substrate scanning at variable speed. The change in the OPD engendered by this targeted implant pattern is the same as for the left-hand set of data, while the throughput increases by 20%. Thus, the introduction of the variable substrate scanning feature to implement the targeted dose pattern 260 increases the substrate throughput by approximately 20% while generating the same effect in terms of reducing OPD, as compared to the case without variable substrate scan speed.

FIG. 9B is a graph that depicts the substrate throughput and substrate OPD response, when subject to non-uniform processing according to different embodiments. In particular, two sets of data are compared, where the left-hand set of data illustrates the results for processing a silicon substrate with a 300 keV Si⁺ ion beam where the geometry of the targeted implant pattern corresponds to the targeted dose pattern 260. However, unlike the scenario of FIG. 8 the substrate is not scanned at variable speed. In this example, 2e15/cm² total ion dose is implanted into the high dose regions 262. The change in the OPD engendered by this targeted implant pattern is 277 mm, while the throughput is 30 wafers per hour. The right-hand set of data illustrates the results for processing a silicon substrate with a 300 keV Si⁺ ion beam where the geometry of the targeted implant pattern corresponds to the geometry of FIG. 8 with substrate scanning at variable speed. The change in the OPD engendered by this targeted implant pattern is also 275 mm, while the throughput is 33 wafers per hour. Thus, the introduction of the variable substrate scanning feature to implement the targeted dose pattern 260 increases the substrate throughput by approximately 10% in this example, while generating the nearly same effect in terms of reducing OPD, as compared to the case without variable substrate scan speed.

FIG. 9C depicts another spot beam shape in a reference plane. FIG. 9D depicts a targeted dose map on a substrate, to be implemented using the spot beam of FIG. 9C. FIG. 9E is another predicted dose map on the substrate based upon a convolution of the spot beam image of FIG. 9C and the targeted dose map of FIG. 9D. As in the scenario of FIG. 5A-FIG. 5C, a spot beam image 268 is determined, and the convolution of spot beam image 268 targeted dose pattern 260 (as discussed above), and a variable spot beam scan rate is used to generate the predicted dose map 270. In this example, the high dose regions 272, low dose regions 274 and middle region 276 are slightly blurred with respect to the high dose region 262, low dose region 264, and middle region 265, respectively, for the targeted dose pattern 260. Note that in this scenario the substrate is scanned at a uniform scan speed.

In particular, the middle region 265 is to be created by beam blanking as described above. Thus, a spot beam corresponding to the spot beam image 268 is to be maintained off a substrate for an interval that is sufficient to create the middle region 265, corresponding to an unexposed portion of the substrate. However, as illustrated in FIG. 9E, the middle region 276 of the predicted dose map 270 includes various grid points that were to receive zero ion dose according to the targeted dose pattern 260, but actually exhibit a finite, non-zero dose. Note that in order to achieve effective beam blanking, the size of the spot ion beam should be taken into account. Thus, in the example of FIG. 9D, the targeted dose pattern 260 is composed of 41 vertical rows, corresponding to 41 different scan lines, for a spot ion beam to scan across the substrate as the substrate is moved in the vertical direction of the figure. The middle region 265 extends to a height corresponding to five rows. Thus, the spot ion beam corresponding to spot beam image 268 should be held off the substrate for sufficient interval so that five rows do not receive any ion dose. However, according to FIG. 9C, the spot beam image 268 extends vertically approximately 8-9 rows, and exhibits variable intensity as a function of position. Thus, a scan recipe to employ spot beam to generate the middle region 265 should allow for the shape of spot beam image 268, and in particular, for the height of the spot beam image along the vertical direction. In the event, as shown in FIG. 9E, the middle region 276 does not extend for a height of five rows, and is particularly pinched in the center, where just two rows receive no ion dose. Accordingly, to determine whether the differences in the predicted dose map 270 and the targeted dose map 260 are below a threshold for processing, the differences in values at each grid point may be determined, such as in the middle regions 276, 265.

As with the case of FIGS. 5A-5C, if an error value representing the difference between the targeted dose pattern 260 and predicted dose pattern 270 is below a threshold, then processing of a substrate may commence using the spot ion beam corresponding to the spot beam image 268.

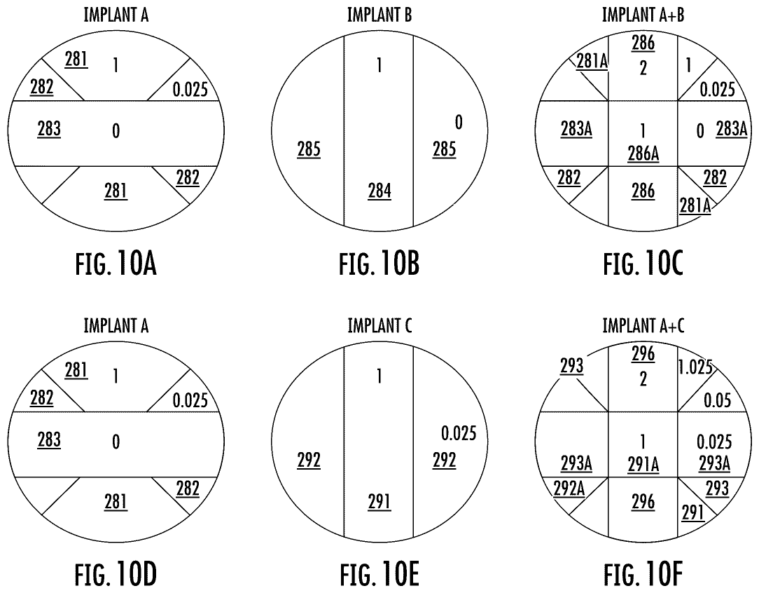

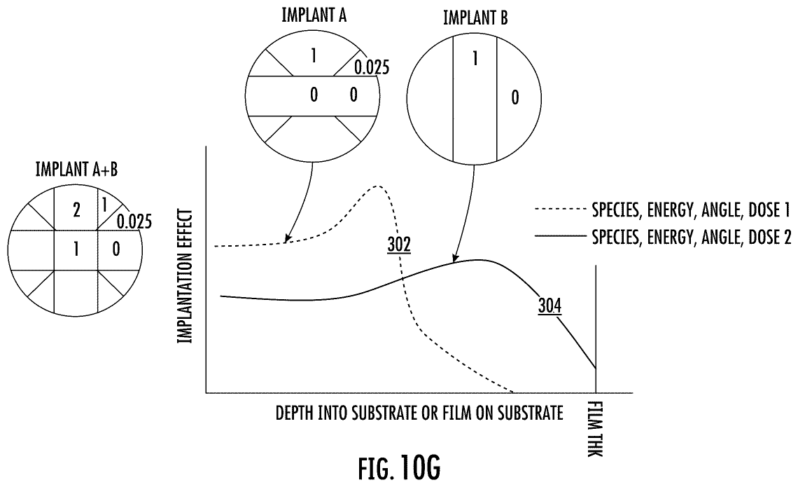

In additional embodiments, useful dose patterns that exhibit higher dose ratios over smaller and more complex areas may be achieved by splitting the maximum ion dose imparted into a substrate into a plurality of separate implants. To this end, FIG. 10A depicts a first targeted dose pattern, FIG. 10B depicts a second targeted dose pattern, while FIG. 10C depicts a composite targeted dose pattern, composed of an addition of the targeted dose pattern of FIG. 10A and the targeted dose pattern of FIG. 10B.

Implant A of FIG. 10A may implemented according to a targeted dose pattern similar to targeted dose pattern 260, with a set of high dose regions 281, a set of low dose regions 282 and zero dose region 283 shaped as a horizontal stripe as shown. In one example, the relative ion dose in the set of high dose regions 281 is 1, while the relative ion dose in the set of low dose regions 282 is 0.025.

Implant B of FIG. 10B may have a targeted dose pattern similar to targeted dose pattern 210, with a high dose region 284, shaped as a vertical stripe, flanked by a set of zero dose regions 285. In one example, the relative ion dose in the set of high dose regions 284 is 1, with respect to the set of high dose regions 281.

When implant A and implant B are performed separately in consecutive fashion on the same substrate, the resulting dose pattern is shown in FIG. 10C. The dose pattern of FIG. 10C includes regions of four different implant doses. The set of low dose regions 282 is not affected, with a relative dose of 0.025. The original shape of the zero dose region 283 is now divided into two portions of zero dose regions 283A. The original set of high dose regions 281 (two wedge shapes) is now divided into four smaller regions, shown as high dose regions 281A, with a relative dose of 1. The original of high dose region 284 is reduced to a smaller region, shown as high dose region 284A, with a relative dose also of 1. Two new, extra high dose regions 286 are defined in the overlap between high dose region 284 and high dose regions 281, with a relative dose of 2.

FIG. 10D depicts a third targeted dose pattern, FIG. 10E depicts a fourth targeted dose pattern, while FIG. 10F depicts a composite targeted dose pattern, composed of an addition of the targeted dose pattern of FIG. 10D and the targeted dose pattern of FIG. 10E.

; Implant A of FIG. 10D may be implemented as described above in regards to FIG. 10A. Implant C of FIG. 10E may have a targeted dose pattern the same as the targeted dose pattern 210, with a high dose regions 291, shaped as a vertical stripe, flanked by a set of low dose regions 292. In one example, the relative ion dose in the set of high dose regions 291 is 1, with respect to the set of high dose regions 281. Moreover, the relative dose of low dose regions 292 may be 0.025.

When implant A and implant C are performed separately in consecutive fashion on the same substrate, the resulting dose pattern is shown in FIG. 10F. The dose pattern of FIG. 10F includes regions of five different implant doses. The original shape of zero dose region 283 is transformed into two separate low dose regions, shown as low dose regions 293A, with a relative dose of 0.025. The original shape of high dose region 291 is transformed into a smaller, central region, shown as high dose region 291A with a relative dose of 1. The original shape of high dose regions 281 is transformed into a set of four higher dose regions, shown as higher dose regions 293, with a relative dose of 1.025. The low dose regions 292 are transformed into a set of four medium dose regions, shown as medium dose regions 292A, with a relative dose of 0.5 Finally, a set of extra high dose regions 296 are defined, as shown, with a relative dose of 2.

FIG. 10G is a composite illustration that depicts the application of multiple implants under different implant conditions to generate a composite targeted dose pattern. In this case, a composite targeted dose pattern may be implemented according to a substrate implant profile, where the substrate implant profile is a convolution of an implant pattern that delineates the dose variation across a substrate, together with a depth profile, that depicts the variation of implantation effects as a function of depth into the substrate. In some non-limiting examples, the depth profile may represent a dopant profile of a given implanting ion species to be used as a dopant; a damage profile that represents the variation of implantation-induced damage as a function of depth, including the generation of interstitials, vacancies, clusters; an amorphization profile that represents an extent of amorphization as a function of depth within a heretofore crystalline substrate. In the particular example of FIG. 10G, the implant pattern of FIG. 10C is to be implemented in a substrate. However, in this example, the implant pattern of implant A involves a first species, with a first ion energy, a first angle of incidence of the ion beam with respect to a substrate, while the implant pattern of implant B involves a second species, with a second ion energy, and a second angle of incidence, where any one or more of the species, energy, and angle of incidence (beam angle) may vary between implant A and implant B. For the purposes of illustration, the implant A may generate a shallower implant, as exemplified by the depth profile shown as curve 302 in the graph of FIG. 10G., while implant B generates a deeper implant, as exemplified by the depth profile specified by the curve 304. Thus, according to the substrate implant profile as disclosed in FIG. 10G, the total ion dose, as well as the implant depth and depth profile of implanted species may vary as a function of regions that were described above with respect to FIG. 10C, in particular.

The approach of FIG. 10G may be useful in a variety of scenarios where independent control of parameters such as ion energy is useful. For example, a substrate may exhibit a complex pattern of OPD, including bow, saddle, and other components, where the exact control of such components may be better achieved by implantation in two or more targeted dose patterns that are produced in two or more implants. For example, a first implant pattern may be implemented in a first implant at a first ion energy, to address a first component of OPD, while a second implant pattern is implemented in a second implant at a second ion energy in order to address a second component of OPD, independently of the first implant.

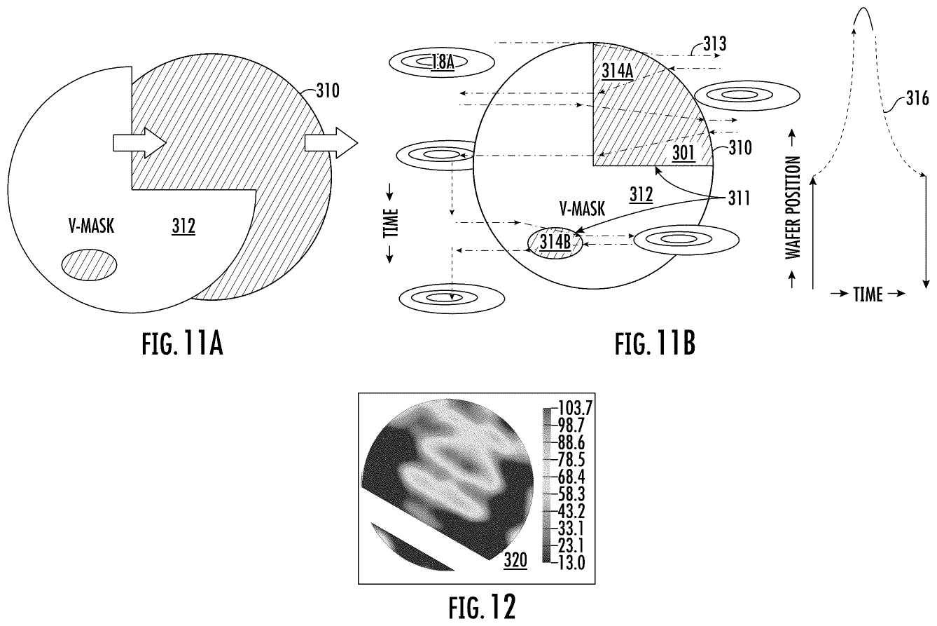

FIG. 11A is an exploded view of a proximity mask and substrate for generating a non-uniform implantation. FIG. 11B is a composite image depicting the geometry and time dependence of the position of a spot ion beam and the substrate of FIG. 11A during an implant process with proximity mask in place, according to yet another embodiment of non-uniform processing. By blocking ions from impinging upon a blocked potion of the substrate 310, underneath the proximity mask, the proximity mask 312 acts in a manner analogous to beam blanking to generate unexposed portions in the substrate 310. In the scenario of FIG. 11B, a spot ion beam 18A is scanned horizontally in a non-uniform manner as defined by the scan path 313. At the same time, the substrate 310 is scanned vertically in a non-uniform manner as defined by the substrate scan path 316. Note that the substrate scan path 316 may include a very high speed (nearly vertical) segment corresponding to when the substrate 310 is positioned so that the proximity mask 312 blocks the spot ion beam 18A. This approach facilitates placing zero dose regions on a substrate, with a shaper transition between a targeted dose pattern 311 that is composed of finite dose regions, shown as regions 314A and region 314B, and a zero dose region (under the proximity mask 312). Moreover, this approach enables more complicated dose region shapes and smaller shapes to be generated with relatively larger-sized spot ion beams.

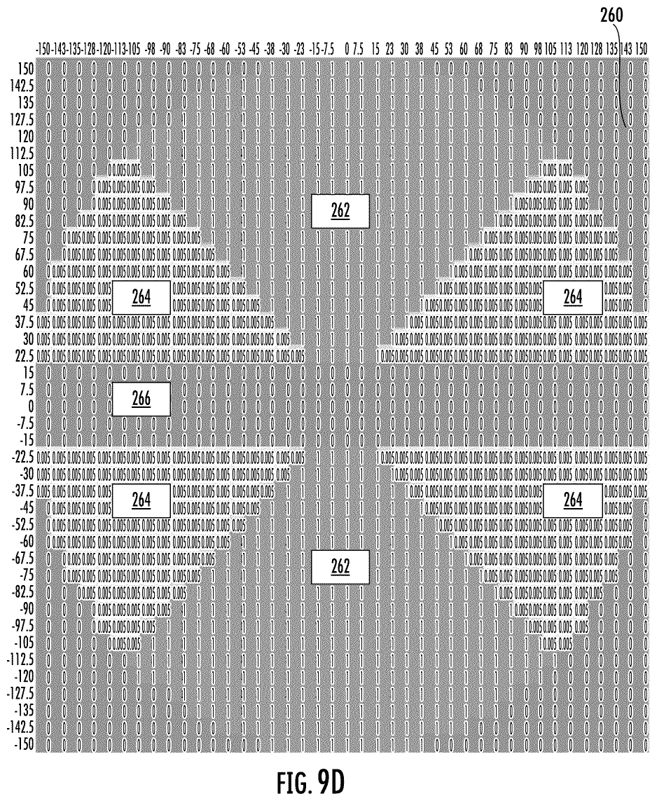

FIG. 12 depicts a complex targeted dose pattern 320. In various embodiments, this targeted dose pattern may be implemented by any suitable combination of techniques as disclosed herein, including employing a variable spot ion beam scan rate, scanning a substrate with variable speed, beam blanking, and the use of Proximity masks.

FIG. 13 depicts an exemplary process flow 1300. At block 1302, a targeted dose pattern is received. The targeted dose pattern may represent a two-dimensional map of ion dose across a surface of a substrate. At block 1304, a measurement of a spot ion beam is received. The spot beam represents an ion beam that is generated for a targeted ion species at a targeted ion energy. The measurement maybe a two-dimensional map of a beam current for a cross-section of the spot ion beam. At block 1306, a scan recipe is received. The scan recipe may specify a variable scan speed for the spot ion beam, beam blanking, and so forth. At block 1308, a predicted dose pattern is generated. In one embodiment, the predicted dose pattern may be generated by a convolution of the spot ion beam map, the targeted dose pattern, and scan recipe. At decision block 1310, a determination is made as to whether a difference between the targeted dose pattern and the predicted dose pattern lies below a threshold. If so, processing of the substrate commences at block 132. If not, the flow proceeds to block 1314 where processing does not commence, and an error message or signal may be generated, so that a user may be informed.

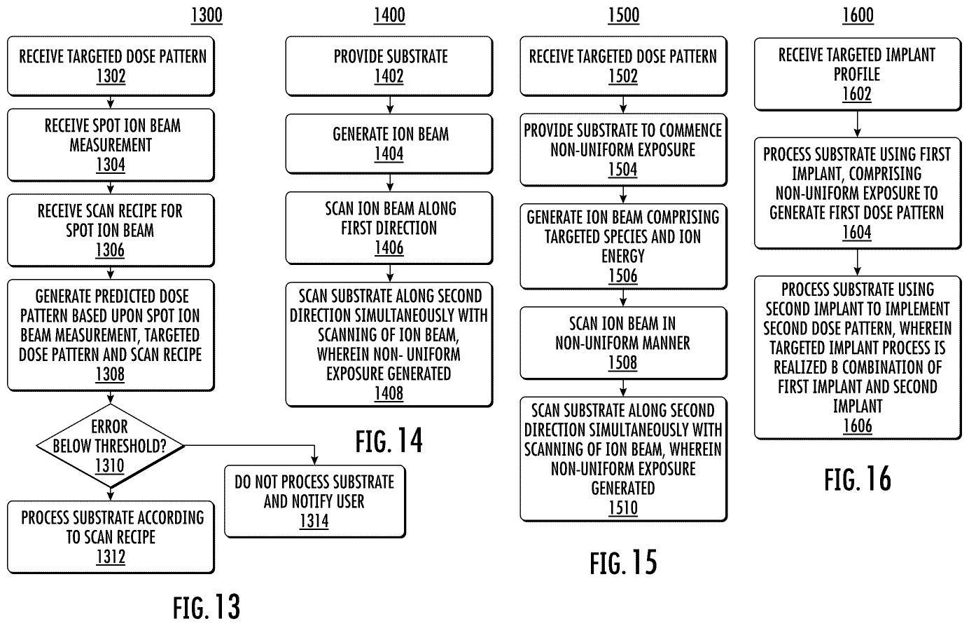

FIG. 14 depicts an exemplary process flow 1400. At block 1402, a substrate is provided. At block 1404, an ion beam is generated for a targeted species at a targeted ion energy. At block 1406, the ion beam is scanned along a first direction, such as back and forth at a relatively high frequency, such as 500 Hz to 2 kHz. In some examples, the spot beam may be scanned in a non-uniform manner, such as by changing the scan speed. At block 1408, the substrate is scanned along a second direction, such as perpendicularly to the first direction. The substrate may be scanned simultaneously with scanning of the spot ion beam to generate a non-uniform exposure of the substrate. In particular, the scanning of the spot ion beam involves beam blanking, where the spot ion beam is maintained off the substrate while the substrate is scanned for a given interval. As such, the combination of the scanning of the substrate and the scanning of the ion beam, including at least one instance of beam blanking, yields an unexposed portion of the substrate that is not exposed to the ion beam after the non-uniform exposure is complete.

FIG. 15 depicts another exemplary process flow 1500. At block 1502, a targeted dose pattern is received that represents a non-uniform dose pattern. At block 1504 a substrate is provided for a non-uniform exposure process. At block 1506, an ion beam is generated for a targeted species at a targeted ion energy. At block 1508, the ion beam is scanned in a non-uniform manner along a first direction, such as back and forth at a relatively high frequency, such as 500 Hz to 2 kHz. At block 1510, the substrate is scanned along a second direction, such as perpendicularly to the first direction. The substrate may be scanned simultaneously with scanning of the substrate to generate a non-uniform exposure of the substrate.

FIG. 16 depicts another exemplary process flow 1600. At block 1602, a targeted substrate implant profile is received. The targeted implant profile may represent a non-uniform dose pattern that is to be generated by implanting a set of species across a plane of a substrate. The targeted implant profile may also represent a non-uniform profile of the set of species as a function of depth within the substrate. In some implementations, the set of species may represent just one species, while in other implementations, the set of species may represent a plurality of different species.

At block 1604, the substrate is processed with a first implant, where the first implant comprises a non-uniform exposure of the substrate using a spot ion beam, for generating a first dose pattern in the substrate. The first dose pattern may comprise any suitable shape of different regions across the surface of the substrate that receive different total doses, respectively, of the set of species.

At block 1606, the substrate is processed with a second implant to implement a second dose pattern in the substrate, where the first implant, in concert with the second implant, generate the targeted implant profile. In some examples the second implant may use a same species for implanting as the first implant. In some examples, the second implant may use a different species for implanting as compared to the first species. In some examples, the first implant and second implant may employ the same species, where an ion energy in the first implant differs from the ion energy of the second implant. In some examples, the second implant involves scanning a spot ion beam in a second non-uniform exposure of the substrate. Optionally, in further embodiments, the substrate may be processed with at least one additional implant, in addition to the first implant and the second implant, where the at least one additional implant may implement an additional dose pattern that may differ from at least one of the first dose pattern and the second dose pattern. Performing at least one additional implant provides further flexibility to implement a targeted implant profile, by allowing parameters such as the ion species, ion angle of incidence, ion energy to be adjusted independently of the first implant and second implant.

Advantages provided by the present embodiments are multifold. In one advantage, the present approach using combinations of non-uniform beam scanning and substrate scanning facilitates an increase in throughput while preserving a targeted effect on substrate properties. Additional embodiments that introduce beam blanking and/or proximity masking to generate a targeted dose pattern will facilitate an improved substrate response, and higher throughput as compared to known approaches.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of processing a substrate, comprising:
subjecting the substrate to a non-uniform exposure, based upon a targeted dose pattern, wherein the targeted dose pattern is a non-uniform pattern, wherein the non-uniform exposure comprises:
during a first interval, scanning an ion beam with respect to the substrate, along a first direction, while the substrate is scanned along a second direction, different from the first direction; and
during a second interval, beam blanking the ion beam while the substrate is scanned along the second direction, wherein an unexposed portion of the substrate remains after the non-uniform exposure, and
wherein a substrate scan speed differs between the first interval and the second interval.

2. The method of claim 1, wherein the ion beam is scanned along the first direction in a uniform manner over an exposed portion of the substrate, different from the unexposed portion of the substrate.

3. The method of claim 1, wherein the ion beam is scanned along the first direction in a non-uniform manner over an exposed portion of the substrate that is different from the unexposed portion of the substrate.

4. The method of claim 3, wherein the ion beam is scanned in a manner to generate a first region and a second region in the exposed portion, wherein the first region comprises a first dose, and the second region comprises a second dose, less than the first dose.

5. The method of claim 4, wherein the first region has a wedge shape.

6. The method of claim 4, wherein the substrate is scanned with a non-uniform velocity along the second direction, wherein a greater exposed region, and a lesser exposed region is generated, in addition to the unexposed portion, wherein a first speed of the substrate at the unexposed portion is relatively greater than a second speed of the substrate at the lesser exposed region, and is relatively greater than a third speed of the substrate at the greater exposed region.

7. The method of claim 1, wherein the non-uniform exposure comprises a first implant, wherein the targeted dose pattern comprises a first dose pattern, the method further comprising:
processing the substrate with a second implant to implement a second dose pattern in the substrate, wherein the first implant, in concert with the second implant, generate a composite dose pattern.

8. The method of claim 7, further comprising:
processing the substrate with at least one additional implant to implement at least one additional dose pattern in the substrate, wherein the first implant, in concert with the second implant and the at least one additional implant generate a composite dose pattern.

9. The method of claim 7, wherein the ion beam comprises a first ion beam, wherein the second implant comprises a second ion beam, and wherein the second implant differs from the first implant in at least one of: an ion energy, a beam angle, and an ion species.

10. A method of processing a substrate, comprising:
subjecting the substrate to a non-uniform exposure, based upon a targeted dose pattern, wherein the targeted dose pattern is a non-uniform pattern, wherein the non-uniform exposure comprises:
scanning a spot ion beam with respect to the substrate, along a first direction, while the substrate is scanned along a second direction, different from the first direction, wherein the spot ion beam is scanned in a non-uniform manner, and
wherein a scan speed of the substrate is varied while the substrate is scanned according to a geometry of the targeted dose pattern.

11. The method of claim 10, wherein the spot ion beam is scanned in a manner to generate a first region, and a second region, wherein the first region comprises a first dose, and the second region comprises a second dose, less than the first dose, and wherein the spot ion beam crosses the first region and the second region in a given scan.

12. The method of claim 11,
wherein the first region has a width that decreases as a function of position along the second direction from an edge of the substrate to a middle of the substrate, and
wherein a scan speed of the substrate is increased as a function of position along the second direction from the edge of the substrate to the middle of the substrate.

13. The method of claim 12, wherein an unexposed portion of the substrate remains after the non-uniform exposure, wherein the unexposed portion extends across the substrate along the first direction, and wherein a scan speed of the substrate is greater at the unexposed portion of the substrate as compared to other regions of the substrate that are exposed to the spot ion beam.

14. The method of claim 10, wherein the non-uniform exposure comprises a first implant, wherein the targeted dose pattern comprises a first dose pattern, the method further comprising:
processing the substrate with a second implant to implement a second dose pattern in the substrate, wherein the first implant, in concert with the second implant, generate a composite dose pattern that is based upon the first dose pattern and the second dose pattern.

15. The method of claim 14, wherein the first implant comprises a first ion beam, wherein the second implant comprises a second ion beam, and wherein the second implant differs from the first implant in at least one of: an ion energy, a beam angle, and an ion species.

16. The method of claim 10, wherein a proximity mask is provided to generate an unexposed portion of the targeted dose pattern by blocking the ion beam from impinging upon a blocked portion of the substrate, and wherein the scan speed of the substrate is greater when the ion beam is positioned adjacent to the blocked portion of the substrate, in comparison to when the ion beam is scanned over an exposed portion of the substrate.

17. A method of processing a substrate, comprising:
receiving a targeted dose pattern for processing the substrate with a spot ion beam;
receiving of spot beam measurement of the spot ion beam;
receiving a scan recipe for the spot ion beam;
generating a predicted dose pattern based upon the spot beam measurement and the scan recipe; and
exposing the substrate to the spot ion beam in a non-uniform exposure, according to the scan recipe in order to implement the targeted dose pattern, when an error between the targeted dose pattern and the predicted dose pattern is below a threshold.

18. The method of claim 17, wherein the predicted dose pattern is generated by convoluting along a dose map grid that represents the targeted dose pattern, a beam shape of the spot ion beam that represents the spot beam measurement, and the scan recipe for the spot ion beam.

19. The method of claim 17, wherein the scan recipe comprises a non-uniform scanning of the spot ion beam, and
wherein the substrate is scanned in a non-uniform manner according to a geometry of the targeted dose pattern.

20. The method of claim 17, wherein the targeted dose pattern comprises an unexposed portion, and wherein the ion beam is blanked by not scanning the spot ion beam over the substrate while the substrate is scanned, so as to generate the unexposed portion.
